(19) United States
(12) Patent Application Publication
(10) Pub. No.: US 2025/0393289 A1
(43) Pub. Date: Dec. 25, 2025

(54) EPITAXIAL STRUCTURE OF GALLIUM NITRIDE TRANSISTOR AND PREPARATION METHOD THEREOF, AND GALLIUM NITRIDE TRANSISTOR

(71) Applicant: Hunan San'an Semiconductor Co., Ltd., Changsha (CN)

(72) Inventors: Deyang Xia, Changsha (CN); Shuai Chen, Changsha (CN); Jie Zhang, Changsha (CN); Biqing Li, Changsha (CN)

(21) Appl. No.: 19/310,401

(22) Filed: Aug. 26, 2025

Related U.S. Application Data
(63) Continuation of application No. PCT/CN2023/134100, filed on Nov. 24, 2023.

(30) Foreign Application Priority Data
Mar. 21, 2023 (CN) 202310282738.0

(51) Int. Cl. H10D 64/68; H10D 30/01; H10D 30/47; H10D 62/85; H10D 64/01

(52) U.S. Cl. CPC H10D 64/685; H10D 30/015; H10D 30/471; H10D 62/8503; H10D 64/01

(57) ABSTRACT

A gallium nitride transistor is provided. Due to the composite layer including a silicon nitride composite structure, it has better sealing properties, which can effectively prevent the corrosion of the barrier layer and other layers in the semiconductor laminated layer by the passivation layer. Moreover, it ensures that the interface and surface between the passivation layer and the barrier layer are smooth, thereby enhancing the passivation effect and consequently improving the performance of the gallium nitride transistor.

### CROSS-REFERENCE TO RELATED APPLICATIONS

This application is a continuation of International Patent Application No. PCT/CN2023/134100, filed on Nov. 24, 2023, which claims the priority of Chinese Patent Application No. 202310282738.0, filed on Mar. 21, 2023, both of which are herein incorporated by reference in their entirety.

### TECHNICAL FIELD

The disclosure relates to the field of semiconductor technologies, and more particularly to an epitaxial structure of a gallium nitride transistor and a preparation method thereof, and the gallium nitride transistor.

### BACKGROUND

During the preparation and application of integrated circuits, the performance of various devices is affected by the concentration of two-dimensional electron gas. In order to reduce the influence on the concentration of two-dimensional electron gas during the preparation process, a passivation layer is generally deposited on the surface of the semiconductor to achieve surface passivation.

In practice, the inventors have found that in the current preparation schemes of the gallium nitride transistor, the passivation layer is usually prepared by plasma enhanced chemical vapor deposition (PECVD) and low pressure chemical vapor deposition (LPCVD). However, the interface between the prepared passivation layer and an aluminum gallium nitride barrier layer is highly susceptible to oxygen impurities. Moreover, during the transfer of the passivation layer, it is prone to contact with oxygen and other impurities in the air, which roughens the surface of the passivation layer, increases gate leakage, introduces trap energy levels in a device layer, and deteriorates the passivation effect, thereby affecting the performance of the device.

### SUMMARY

In order to solve the above technical problems, the disclosure provides an epitaxial structure of a gallium nitride transistor. A composite layer including a composite structure with silicon nitride is directly formed on a semiconductor laminated layer. The semiconductor laminated layer includes a cap layer facing away from the semiconductor base material. In the composite layer, a proportion of the silicon nitride gradually increases along a direction from the semiconductor base material to the semiconductor laminated layer, ensuring that the proportion of the silicon nitride facing towards the semiconductor laminated layer is less than the proportion of the silicon nitride facing away from the semiconductor laminated layer. As a result, the composite layer including the silicon nitride has better sealing properties, which effectively prevents a passivation layer of the gallium nitride transistor from corroding a barrier layer, also ensures that the interface and surface between the passivation layer and the barrier layer are smooth, and prevents other impurities from being introduced into the passivation layer, thereby enhancing the passivation effect and improving the performance of the gallium nitride transistor.

### BRIEF DESCRIPTION OF DRAWINGS

FIG. 1 illustrates a schematic flowchart of a preparation method of a gallium nitride transistor according to an embodiment of the disclosure.

FIG. 2 illustrates a schematic structural view of a semiconductor base material according to the embodiment of the disclosure.

FIG. 3 illustrates a schematic structural view of forming a semiconductor laminated layer on the semiconductor base material according to the embodiment of the disclosure.

FIG. 4 illustrates a schematic structural view of forming a composite layer on the semiconductor laminated layer according to the embodiment of the disclosure.

FIG. 5 illustrates a schematic structural view of an island structure formed by silicon nitride in the composite layer according to the embodiment of the disclosure.

FIG. 6 illustrates a schematic structural view of an epitaxial structure of the gallium nitride transistor according to the embodiment of the disclosure.

FIG. 7 illustrates a schematic structural view of the gallium nitride transistor including a source electrode, a gate electrode and a drain electrode according to the embodiment of the disclosure.

FIG. 8 illustrates a schematic flowchart of a preparation method of a gallium nitride transistor according to another embodiment of the disclosure.

FIG. 9 illustrates a schematic structural view of forming a multi-layer composite layer on a semiconductor laminated layer according to the another embodiment of the disclosure.

FIG. 10 illustrates a schematic structural view of disposing a source electrode, a gate electrode and a drain electrode on the semiconductor laminated layer according to the another embodiment of the disclosure.

FIG. 11 illustrates a schematic structural view of forming a passivation layer on the composite layer according to the another embodiment of the disclosure.

### DETAILED DESCRIPTION OF EMBODIMENTS

A detailed explanation of the disclosure will be provided below in conjunction with the accompanying drawings and embodiments.

In the current preparation schemes of the gallium nitride transistor, a passivation layer is usually prepared by PECVD and LPCVD. However, during the preparing process, the interface between the passivation layer and a semiconductor layer is highly susceptible to oxygen impurities. Moreover, when using PECVD or LPCVD equipment to deposit the passivation layer, an epitaxial wafer needs to be removed from the epitaxial equipment and then transferred to the PECVD or LPCVD equipment. During this process, it is prone to contact with oxygen and other impurities in the air. Even with cleaning, it is difficult to completely eliminate the residual impurities. The impurities not only increase gate leakage, but also introduce trap energy levels in the device layer, and deteriorates the passivation effect, thereby affecting the performance of the gallium nitride transistor.

Therefore, a preparation method of a gallium nitride transistor is proposed to avoid the corrosion of the barrier layer by the passivation layer, and to ensure that the interface and surface between the passivation layer and the barrier layer are smooth, while preventing other impurities from being introduced into the passivation layer. This enhances the passivation effect and thereby improves the performance of the gallium nitride transistor.

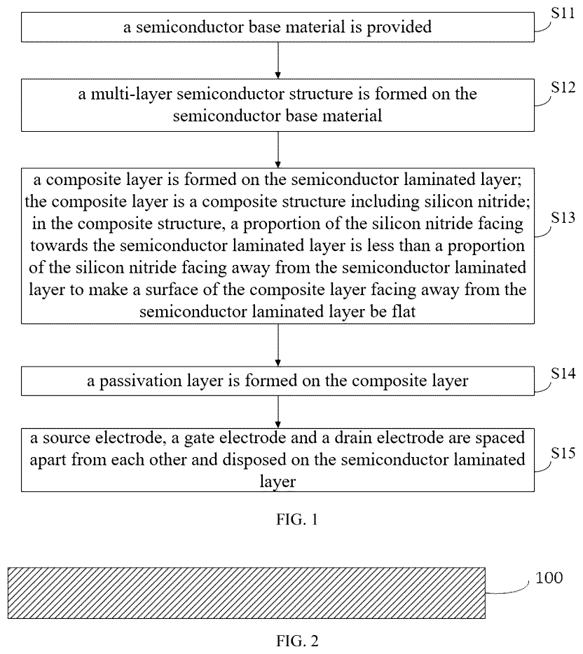

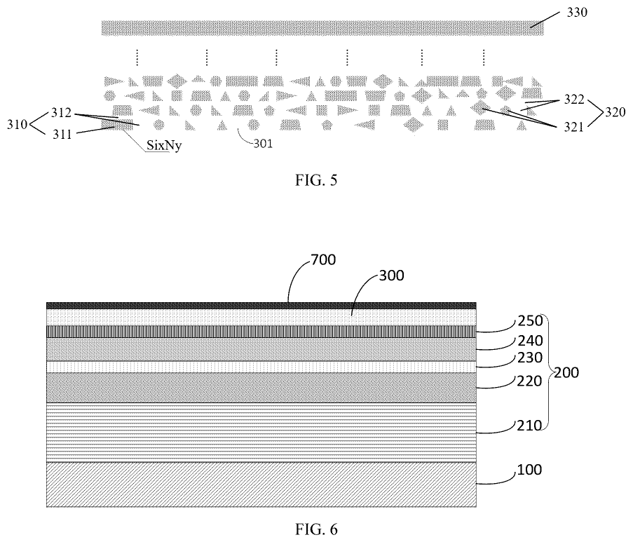

Please refer to FIGS. 1-7, as shown in FIG. 1, in an embodiment, the preparation method of the gallium nitride transistor includes following steps S11-S15.

S11, a semiconductor base material 100 is provided.

Specifically, referring to FIG. 2, FIG. 2 illustrates a schematic structural view of the semiconductor base material 100 according to the embodiment of the disclosure. It can be understood that, as shown in FIG. 2, the semiconductor base material 100 includes a substrate. The substrate can be one of a silicon substrate, a silicon carbide substrate, a gallium nitride substrate, a germanium substrate, and a semiconductor on insulator (SOI) substrate (e.g., silicon on insulator, germanium on insulator, or silicon germanium on insulator) etc. It is understood by those skilled in the art that the substrate is not limited and can be selected according to the specific application.

In other embodiments, the semiconductor base material 100 may further include device structures, isolation structures, dielectric layers, or interconnect structures located in or on the substrate (not shown in figures). Those skilled in the art would understand that the device structures, isolation structures, dielectric layers, or interconnect structures are not limited in any way and can be selected according to the specific application.

S12, a multi-layer semiconductor structure 200 is formed on the semiconductor base material 100.

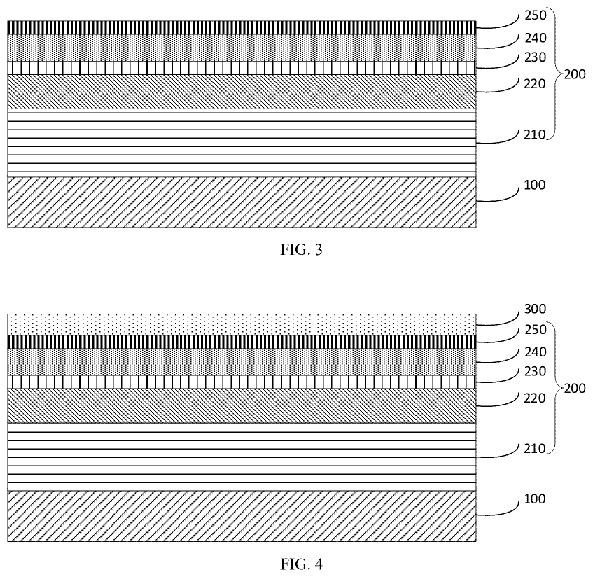

Referring to FIG. 3, FIG. 3 illustrates a schematic structural diagram of forming the multi-layer semiconductor structure 200 on the semiconductor base material 100 according to the embodiment of the disclosure. As shown in FIG. 3, the gallium nitride transistor includes the semiconductor base material 100 and the multi-layer semiconductor structure 200 formed on the semiconductor base material 100. The multi-layer semiconductor structure 200 may include three layers, five layers, or ten layers etc., depending on the specific requirements of the gallium nitride transistor. For ease of description, the multi-layer semiconductor structure 200 can also be referred to as a semiconductor laminated layer 200.

Specifically, in the embodiment, taking five semiconductor layers as an example, a first semiconductor layer 210, a second semiconductor layer 220, a third semiconductor layer 230, a fourth semiconductor layer 240, and a fifth semiconductor layer 250 are sequentially formed on the semiconductor base material 100 in that order.

In some embodiments, the first semiconductor layer 210 may be a buffer layer, a material of the first semiconductor layer 210 may be semi-insulating, high-resistance, high-quality gallium nitride (GaN), and a thickness of the first semiconductor layer 210 may be in a range of 3-4 micrometers (μm). The second semiconductor layer 220 may be a channel layer, made of high-quality gallium nitride, with a thickness in a range of 150-250 nm, such as 200 nm. The third semiconductor layer 230 can be an insertion layer, a material of the third semiconductor layer 230 may be aluminum nitride (AlN), and a thickness of the third semiconductor layer 230 may be in a range of 0.1-1 nm. The fourth semiconductor layer 240 may be a barrier layer, a material of the fourth semiconductor layer 240 may be aluminum gallium nitride (AlGaN), and a thickness of the fourth semiconductor layer 240 may be in a range of 15-30 nm. The fifth semiconductor layer 250 may be a cap layer, a material of the fifth semiconductor layer 250 may be gallium nitride, or may be AlN, indium aluminum nitride (InAlN), or AlGaN, the fifth semiconductor layer 250 is also referred to as an intrinsic gallium nitride layer, a thickness of the fifth semiconductor layer 250 is in a range of 0.3-5 nm. For example, the thickness of the fifth semiconductor layer 250 is in a range of 0.3-5 nm. For example, the thickness of the fifth semiconductor layer 250 is 0.5 nm.

Specifically, in the embodiment, the semiconductor laminated layer 200 is deposited by metal organic chemical vapor deposition (MOCVD). For example, a gallium nitride buffer layer is grown on the semiconductor base material 100 by the MOCVD, a gallium nitride channel layer is grown on the gallium nitride buffer layer by the MOCVD, an AlN insertion layer is grown on the gallium nitride channel layer by the MOCVD, an AlGaN barrier layer is grown on the AlN insertion layer by the MOCVD, and a gallium nitride cap layer is grown on the AlGaN barrier layer by the MOCVD.

S13, a composite layer 300 is formed on the semiconductor laminated layer 200. Specifically, the composite layer 300 is a composite structure including silicon nitride. In the composite structure, a proportion of the silicon nitride facing towards the semiconductor laminated layer 200 is less than a proportion of the silicon nitride facing away from the semiconductor laminated layer 200 to make a surface of the composite layer 300 facing away from the semiconductor laminated layer 200 be flat.

Referring to FIG. 4, FIG. 4 illustrates a schematic structural diagram of forming the composite layer 300 on the semiconductor laminated layer 200 according to the embodiment of the disclosure. FIG. 5 illustrates a schematic structural view of an island structure formed by silicon nitride in the composite layer 300. As shown in FIG. 4, the gallium nitride transistor includes the semiconductor base material 100, the multi-layer semiconductor structure 200 formed on the semiconductor base material 100, and the composite layer 300 formed on the semiconductor laminated layer 200.

Specifically, the composite layer 300 is grown in situ by the MOCVD. That is, the first semiconductor layer 210, the second semiconductor layer 220, the third semiconductor layer 230, the fourth semiconductor layer 240, the fifth semiconductor layer 250, and the composite layer 300 are sequentially formed on the semiconductor base material 100 by the MOCVD in that order. During a growing process of the composite layer 300, as shown in FIG. 5, the proportion of the silicon nitride facing towards the semiconductor laminated layer 200 is less than the proportion of the silicon nitride facing away from the semiconductor laminated layer 200, that is, the distribution of the silicon nitride in the composite layer 300 gradually increases from bottom to top, to make the island structure formed by silicon nitride is filled with other materials in the composite layer 300. In other words, the discontinuous porous film formed by silicon nitride during the deposition process is filled with other materials in the composite layer 300, which may effectively prevent the semiconductor laminated layer 200 thereunder from being corroded, ensuring that the interface and the corresponding surface between the composite layer 300 and the semiconductor laminated layer 200 are smooth, thereby protecting the underlying semiconductor layer 200.

In some embodiments, as shown in FIG. 5, the island structure formed by silicon nitride (SixNy) in the composite layer 300 is also referred to as silicon nitride islands, i.e., numerous silicon nitride islands are formed in the composite layer 300, and gaps 301 between the silicon nitride islands become progressively smaller from the bottom to the top.

S14, a passivation layer 700 is formed on the composite layer 300. A material of the passivation layer 700 may be silicon nitride.

It should be noted that the composite layer 300 can be understood as a transition region between the cap layer and the passivation layer 700 above the cap layer. By using the composite layer 300 made of silicon nitride/gallium nitride as the transition, the issue of silicon nitride forming porous films on the gallium nitride cap layer can be effectively resolved when regrowing the silicon nitride passivation layer 700, and the corrosive effect of silane (SiH₄) on the underlying Group III nitrides (such as gallium nitride) can be suppresses during the growth of the silicon nitride passivation layer, ultimately obtaining a smooth passivation layer 700. Moreover, the grown composite layer 300 can also effectively avoid particle contamination introduced by secondary deposition.

S15, a source electrode 400, a gate electrode 500 and a drain electrode 600 are spaced apart from each other and disposed on the semiconductor laminated layer 200.

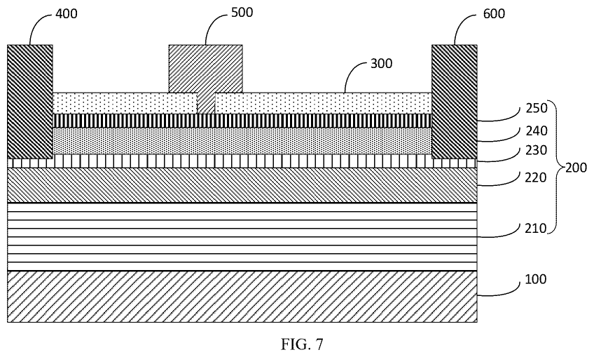

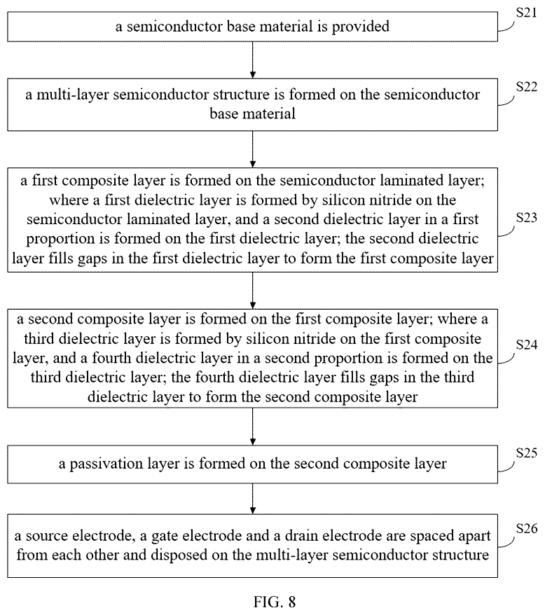

Referring to FIG. 7, FIG. 7 illustrates a schematic structural view of the gallium nitride transistor including the source electrode 400, the gate electrode 500 and the drain electrode 600 according to the embodiment of the disclosure. As shown in FIG. 7, the gallium nitride transistor includes the semiconductor base material 100, the multi-layer semiconductor structure 200 formed on the semiconductor base material 100, the composite layer 300 formed on the semiconductor laminated layer 200, the passivation layer 700 formed on the composite layer 300, and the source electrode 400, the gate electrode 500 and the drain electrode 600 disposed on the semiconductor laminated layer 200. The source electrode 400, the gate electrode 500 and the drain electrode 600 are at least configured to be electrically insulated from each other by the passivation layer 700.

Specifically, in the embodiment, the first semiconductor layer 210, the second semiconductor layer 220, the third semiconductor layer 230, and the composite layer 300 are sequentially formed on the semiconductor base material 100 by the MOCVD in that order, and the source electrode 400, the gate electrode 500 and the drain electrode 600 are correspondingly disposed on the semiconductor laminated layer 200.

In this process, the cap layer 200, the composite layer 300, and the passivation layer 700 need to be etched to form a source contact hole, a gate contact hole, and a drain contact hole. The source electrode 400 is formed in the source contact hole, the gate electrode 500 is formed in the gate contact hole, and the drain electrode 600 is formed in the drain contact hole. The source electrode 400, the gate electrode 500, and the drain electrode 600 are spaced apart from each other, with the gate electrode 500 located between the source electrode 400 and the drain electrode 600. It should be noted that, in some embodiments, the source and drain contact holes also penetrate through the fourth semiconductor layer 240, i.e., the barrier layer, to allow the source electrode 400 and the drain electrode 600 to be conductive through the semiconductor layers.

Selectively, the cap layer, the composite layer 300, and the passivation layer 700 can be etched by dry-etching.

In the embodiment, during the forming of the composite layer 300 using the MOCVD method, silicon nitride is gradually increased to form the composite layer 300, allowing the silicon nitride to form a discontinuous, porous film during the deposition process, which is then filled with other materials in the composite layer 300. This effectively prevents the underlying semiconductor layer 200 from being corroded, ensuring that the interface and the corresponding surface between the composite layer 300 and the semiconductor laminated layer 200 are smooth, protecting the underlying semiconductor layer 200, and thereby significantly enhancing the electrical performance of the gallium nitride transistor.

It should be noted that, in the above embodiments, steps S11-S13 can be used to prepare an epitaxial structure of the gallium nitride transistor.

Referring to FIG. 8, FIG. 8 illustrates a flowchart of a preparation method of a gallium nitride transistor according to other embodiments of the disclosure.

As shown in FIG. 8, the preparation method of the gallium nitride transistor in this embodiment includes following steps S21-S26.

S21, a semiconductor base material 100 is provided.

S22, a multi-layer semiconductor structure 200 is formed on the semiconductor base material 100.

S23, a first composite layer 310 is formed on the semiconductor laminated layer 200.

Specifically, a first dielectric layer 311 is formed by silicon nitride on the semiconductor laminated layer 200, and a second dielectric layer 312 in a first proportion is formed on the first dielectric layer 311. The second dielectric layer 312 fills gaps 301 in the first dielectric layer 311 to form the first composite layer 310. In some embodiments, the second dielectric layer 312 fills the gaps 301 in the first dielectric layer 311 and covers a surface of the first dielectric layer 311 facing away from the semiconductor laminated layer 200.

S24, a second composite layer 320 is formed on the first composite layer 310.

Specifically, a third dielectric layer 321 is formed by silicon nitride on the first composite layer 310, and a fourth dielectric layer 322 in a second proportion is formed on the third dielectric layer 321. The fourth dielectric layer 322 fills gaps 301 in the third dielectric layer 321 to form the second composite layer 320. In some embodiments, the fourth dielectric layer 322 fills the gaps 301 in the third dielectric layer 321 and covers a surface of the third dielectric layer 321 facing away from the semiconductor laminated layer 200.

S25, a passivation layer 700 is formed on the second composite layer 320.

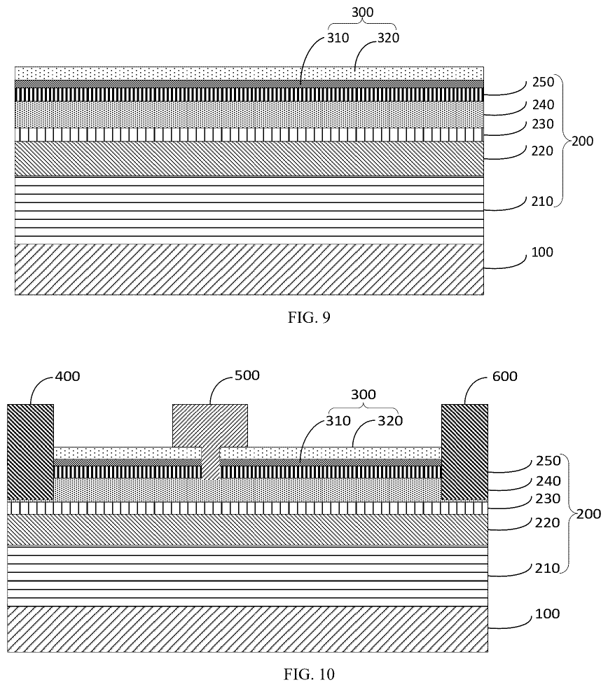

Referring to FIG. 9, FIG. 9 illustrates a schematic structural view of forming a multi-layer composite layer 300 on the semiconductor laminated layer 200 according to the embodiment of the disclosure. As shown in FIG. 9, the gallium nitride transistor includes the semiconductor base material 100, the multi-layer semiconductor structure 200 formed on the semiconductor base material 100, and the composite layer 300 formed on the semiconductor laminated layer 200. The composite layer 300 includes the first composite layer 310 and the second composite layer 320, that is, the first composite layer 310 is formed on the semiconductor laminated layer 200, and the second composite layer 320 is formed on the first composite layer 310.

Specifically, the composite layer 300 may be a silicon nitride/gallium nitride composite layer. A proportion of the silicon nitride in the first composite layer 310 is less than a proportion of the silicon nitride in the second composite layer 320, that is, the distribution of the silicon nitride in the silicon nitride/gallium nitride composite layer gradually increases from the bottom to the top.

The first dielectric layer 311 is a silicon nitride layer, the second dielectric layer 312 is a gallium nitride layer, and the gallium nitride layer as the second dielectric layer 312 fills the gaps 301 of the silicon nitride layer as the first dielectric layer 311 to thereby form the first composite layer 310. The third dielectric layer 321 is a silicon nitride layer, the fourth dielectric layer 322 is a gallium nitride layer, and the gallium nitride layer as the fourth dielectric layer 322 fills the gaps 301 of the silicon nitride layer as the third dielectric layer 321 to thereby form the second composite layer 320.

Specifically, in the embodiment, the semiconductor laminated layer 200 is deposited by the MOCVD. For example, a gallium nitride buffer layer is grown on the semiconductor base material 100 by the MOCVD, a gallium nitride channel layer is grown on the gallium nitride buffer layer by the MOCVD, an AlN insertion layer is grown on the gallium nitride channel layer by the MOCVD, an AlGaN barrier layer is grown on the AlN insertion layer by the MOCVD, and a gallium nitride cap layer is grown on the AlGaN barrier layer by the MOCVD. After growing the gallium nitride cap layer, a small amount of first silicon nitride islands are grown on the gallium nitride cap layer to grow the first dielectric layer 311; consequently, gallium nitride is grown on the first silicon nitride island layer to grow the second dielectric layer 312, and the gaps 301 between the first silicon nitride islands are filled with the gallium nitride to form the first composite layer 310. Second silicon nitride islands are grown on the first composite layer 310 to grow the third dielectric layer 321, the gaps 301 between the second silicon nitride islands are smaller relative to the gaps 301 between the first silicon nitride islands, gallium nitride is grown on the second silicon nitride islands to grow the fourth dielectric layer 322, and the gaps 301 between the second silicon nitride islands are filled with the gallium nitride to form the second composite layer 320.

Exemplarily, referring to FIG. 5, an arrangement density of the first silicon nitride island structure of the first dielectric layer 311 is less than an arrangement density of the second silicon nitride island structure of the third dielectric layer 321.

Exemplarily, referring to FIG. 5, an average width of the gaps 301 defined in the first silicon nitride island structure of the first dielectric layer 311 is greater than an average width of the gaps 301 defined in the second silicon nitride island structure of the third dielectric layer 321.

In some embodiments, silicon nitride is grown on the second composite layer 320 to grow a fifth dielectric layer 330 on the second composite layer 320, to thereby make a surface of the second composite layer 320 a flat thin film. A thickness of the composite layer 300 may be in a range of 2-3 nm. The composite layer 300 includes: the first composite layer 310 formed by the first dielectric layer 311 and the second dielectric layer 312, the second composite layer 320 formed by the third dielectric layer 321 and the fourth dielectric layer 322, and the fifth dielectric layer 330. The first dielectric layer 311, the third dielectric layer 321 and the fifth dielectric layer 330 may be silicon nitride layers. The second dielectric layer 312 and the fourth dielectric layer 322 may be gallium nitride layers.

In other embodiments, the composite layer 300 may include multiple composite layers, such as four or six composite layers, which can be set according to actual situations. Taking four composite layers as an example, the composite layer 300 may include a first composite layer 310, a second composite layer 320, a third composite layer, and a fourth composite layer which are sequentially stacked in that order. A proportion of the silicon nitride in the first composite layer 310 is less than a proportion of the silicon nitride in the second composite layer 320, the proportion of the silicon nitride in the second composite layer 320 is less than a proportion of the silicon nitride in the third composite layer, the proportion of the silicon nitride in the third composite layer is less than a proportion of the silicon nitride in the fourth composite layer. That is, the proportion of the silicon nitride gradually increases from the bottom to the top. For example, during a process of growing the silicon nitride, SiH₄/ammonia (NH₃) are used for growing, and a ratio of the SiH₄/NH₃ is in a range of 0.2×10⁶-90×10⁶. In this range, the ratio of the SiH₄/NH₃ is increased layer by layer, with each increment being approximately 10 to 30, and it can be increased proportionally.

In another embodiment, after growing the multiple composite structures on the gallium nitride cap layer, the silicon nitride dielectric layer is grown. The composite structure is a silicon nitride/gallium nitride composite structure with gradually increasing silicon nitride content, and its thickness and structure can be arranged periodically in proportion. The epitaxial structure of the gallium nitride-based high electron mobility transistor (HEMT) including this composite structure can also effectively solve the corrosion problem of Group III nitrides by SiH₄ during the growth of silicon nitride, while avoiding particle contamination introduced by secondary deposition of the dielectric layer.

S26, a source electrode 400, a gate electrode 500 and a drain electrode 600 are spaced apart from each other and disposed on the multi-layer semiconductor structure 200.

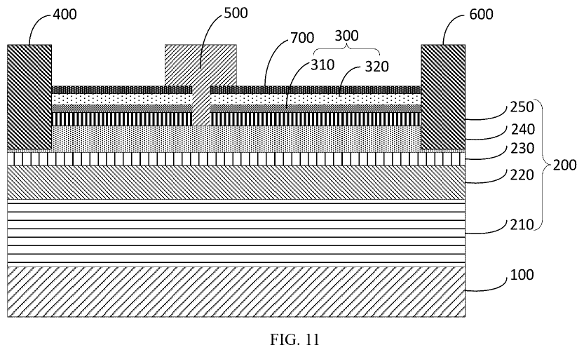

Referring to FIG. 10, FIG. 10 illustrates a schematic structural view of disposing the source electrode, the gate electrode and the drain electrode on the semiconductor laminated layer 200 according to the embodiment of the disclosure. As shown in FIG. 10, the gallium nitride transistor includes the semiconductor base material 100, the multi-layer semiconductor structure 200 formed on the semiconductor base material 100, the composite layer 300 formed on the semiconductor laminated layer 200, and the source electrode 400, the gate electrode 500 and the drain electrode 600 disposed on the semiconductor laminated layer 200. The composite layer 300 includes the first composite layer 310 and the second composite layer 320, that is, the first composite layer 310 is formed on the semiconductor laminated layer 200, and the second composite layer 320 is formed on the first composite layer 310.

Specifically, by using the MOVCD method, a gallium nitride buffer layer is grown on the semiconductor base material 100, a gallium nitride channel layer is grown on the gallium nitride buffer layer, an AlN insertion layer is grown on the gallium nitride channel layer, an AlGaN barrier layer is grown on the AlN insertion layer by the MOCVD, and a gallium nitride cap layer is grown on the AlGaN barrier layer. After growing the gallium nitride cap layer, a small amount of first silicon nitride islands are grown on the gallium nitride cap layer to grow the first dielectric layer 311; consequently, gallium nitride is grown on the first silicon nitride island layer to grow the second dielectric layer 312, and the gaps 301 between the first silicon nitride islands are filled with the gallium nitride to form the first composite layer 310. Second silicon nitride islands are grown on the first composite layer 310 to grow the third dielectric layer 321, the gaps 301 between the second silicon nitride islands are smaller relative to the gaps 301 between the first silicon nitride islands, gallium nitride is grown on the second silicon nitride islands to grow the fourth dielectric layer 322, and the gaps 301 between the second silicon nitride islands are filled with the gallium nitride to form the second composite layer 320. The composite layer 300 need to be etched to form a source contact hole, a gate contact hole, and a drain contact hole. The source electrode 400 is formed in the source contact hole, the gate electrode 500 is formed in the gate contact hole, and the drain electrode 600 is formed in the drain contact hole. The source electrode 400, the gate electrode 500, and the drain electrode 600 are spaced apart from each other, with the gate electrode 500 located between the source electrode 400 and the drain electrode 600, and at least located on the cap layer.

In an embodiment, referring to FIG. 11, FIG. 11 illustrates a schematic structural view of forming a passivation layer 700 on the composite layer 300 according to the embodiment of the disclosure. As shown in FIG. 11, the gallium nitride transistor includes the semiconductor base material 100, the multi-layer semiconductor structure 200 formed on the semiconductor base material 100, and the composite layer 300 formed on the semiconductor laminated layer 200. The composite layer 300 includes the first composite layer 310 and the second composite layer 320, that is, the first composite layer 310 is formed on the semiconductor laminated layer 200, and the second composite layer 320 is formed on the first composite layer 310. A sixth dielectric layer is formed on the second composite layer 320, i.e., the passivation layer 700 is formed on the second composite layer 320. The source electrode 400, the gate electrode 500 and the drain electrode 600 disposed on the passivation layer 700. The composite layer 300 and the passivation layer 700 need to be etched to form a source contact hole, a gate contact hole, and a drain contact hole penetrating through the composite layer 300 and the passivation layer 700. The source electrode 400 is formed in the source contact hole, the gate electrode 500 is formed in the gate contact hole, and the drain electrode 600 is formed in the drain contact hole. The source electrode 400, the gate electrode 500, and the drain electrode 600 are spaced apart from each other, with the gate electrode 500 located between the source electrode 400 and the drain electrode 600.

The sixth dielectric layer can be a silicon nitride layer, that is, silicon nitride is grown on the second composite layer 320 to form the passivation layer 700 made of silicon nitride. A thickness of the passivation layer 700 is in a range of 3-5 nm. To suppress the surface electron states in HEMTs, a silicon nitride passivation layer is commonly deposited to achieve surface passivation of AlGaN/gallium nitride. The silicon nitride passivation layer not only suppresses surface states in the device but also isolates impurity atoms and molecules, thereby relieving the current collapse effect in AlGaN/gallium nitride HEMT devices. During the conventional direct growth of silicon nitride, the source gas SiH₄ can corrode the underlying Group III nitrides, and silicon nitride deposition tends to form discontinuous, porous films, which can lead to subsequent corrosion of the underlying Group III nitrides by SiH₄, resulting in uneven interfaces and surfaces, ultimately causing damage to the barrier layer of the device. The disclosure proposes an in situ MOCVD growth method for a silicon nitride/gallium nitride composite layer, using the silicon nitride/gallium nitride composite layer as a transition layer to achieve the growth of the silicon nitride to thereby achieve the surface passivation of the AlGaN/gallium nitride HEMT. This method effectively addresses problems of poor passivation layer uniformity and damage to the device barrier layer caused by the corrosion of group III nitrides by the reaction source SiH₄ during the epitaxial growth process when growing the silicon nitride layer on the gallium nitride. A new in situ MOCVD growth approach for the silicon nitride passivation layer in the HEMT is provided. The epitaxial preparation is simple to implement, highly repeatable and controllable, and is more suitable for large-scale production.

In the embodiment, during the formation of the composite layer 300 using the MOCVD method, silicon nitride is gradually increased to form the composite layer 300. The grown dielectric layer can also effectively avoid particle contamination introduced by secondary epitaxy. Moreover, this method is simple to implement through epitaxial preparation and has high repeatability and controllability, making it more suitable for large-scale production. Correspondingly, different proportions of silicon nitride/gallium nitride composite layers are formed from the bottom to the top, so that the discontinuous porous film formed by silicon nitride during the deposition process is filled with gallium nitride in the composite layer 300. This effectively prevents the underlying semiconductor layer 200 from being corroded, ensuring that the interface and the corresponding surface between the composite layer 300 and the semiconductor laminated layer 200 are smooth, protecting the underlying semiconductor layer 200 and thereby significantly enhances the electrical performance of the gallium nitride transistor.

In an embodiment, a chip is further provided. The chip includes the above gallium nitride transistor.

What is claimed is:

1. An epitaxial structure of a gallium nitride transistor, comprising:
a semiconductor base material;
a semiconductor laminated layer, disposed on the semiconductor base material, wherein the semiconductor laminated layer comprises a cap layer facing away from the semiconductor base material;
a composite layer, disposed on the cap layer, wherein the composite layer is a composite structure comprising silicon nitride, and in the composite structure, a proportion of the silicon nitride facing towards the semiconductor laminated layer is less than a proportion of the silicon nitride facing away from the semiconductor laminated layer; and
a passivation layer, disposed on the composite layer.

2. The epitaxial structure of the gallium nitride transistor as claimed in claim 1, wherein a thickness of the cap layer is in a range of 0.3-5 nanometers (nm).

3. The epitaxial structure of the gallium nitride transistor as claimed in claim 1, wherein a material of the cap layer is intrinsic gallium nitride.

4. The epitaxial structure of the gallium nitride transistor as claimed in claim 1, wherein the composite layer comprises at least two layers comprising:
a first composite layer, disposed on the semiconductor laminated layer, wherein the first composite layer comprises:
a first dielectric layer, disposed on the semiconductor laminated layer and configured as a first silicon nitride island structure; and
a second dielectric layer, connected to the first silicon nitride island structure, located in gaps of the first silicon nitride island structure, and flush with the first silicon nitride island structure; and
a second composite layer, disposed on the first composite layer, wherein the second composite layer comprises:
a third dielectric layer, disposed on the first composite layer, and configured as a second silicon nitride island structure; and
a fourth dielectric layer, connected to the second silicon nitride island structure, located in gaps of the second silicon nitride island structure, and flush with the second silicon nitride island structure.

5. The epitaxial structure of the gallium nitride transistor as claimed in claim 4, wherein an arrangement density of the first silicon nitride island structure of the first dielectric layer is less than an arrangement density of the second silicon nitride island structure of the third dielectric layer.

6. The epitaxial structure of the gallium nitride transistor as claimed in claim 4, wherein an average width of the gaps defined in the first silicon nitride island structure of the first dielectric layer is greater than an average width of the gaps defined in the second silicon nitride island structure of the third dielectric layer.

7. The epitaxial structure of the gallium nitride transistor as claimed in claim 4, wherein the composite layer further comprises a fifth dielectric layer disposed on the second composite layer, and a surface of the fifth dielectric layer facing away from the semiconductor laminated layer is flat surface.

8. The epitaxial structure of the gallium nitride transistor as claimed in claim 7, wherein a material of the fifth dielectric layer is the silicon nitride.

9. The epitaxial structure of the gallium nitride transistor as claimed in claim 4, wherein a material of each of the second dielectric layer and the fourth dielectric layer is gallium nitride.

10. A gallium nitride transistor, comprising:
a semiconductor base material;
a semiconductor laminated layer, disposed on the semiconductor base material, wherein the semiconductor laminated layer comprises a cap layer facing away from the semiconductor base material;
a composite layer, disposed on the cap layer, wherein the composite layer is a composite structure comprising silicon nitride, and in the composite structure, a proportion of the silicon nitride facing towards the semiconductor laminated layer is less than a proportion of the silicon nitride facing away from the semiconductor laminated layer;
a passivation layer, disposed on the composite layer; and
a source electrode, a gate electrode and a drain electrode spaced apart from each other and disposed on the semiconductor laminated layer.

11. The gallium nitride transistor as claimed in claim 10, wherein a thickness of the cap layer is in a range of 0.3-5 nm.

12. The gallium nitride transistor as claimed in claim 10, wherein a material of the cap layer is intrinsic gallium nitride.

13. The gallium nitride transistor as claimed in claim 10, wherein the composite layer comprises at least two layers comprising:
a first composite layer, disposed on the semiconductor laminated layer, wherein the first composite layer comprises:
a first dielectric layer, disposed on the semiconductor laminated layer and configured as a first silicon nitride island structure; and
a second dielectric layer, connected to the first silicon nitride island structure, located in gaps of the first silicon nitride island structure, and flush with the first silicon nitride island structure; and
a second composite layer, disposed on the first composite layer, wherein the second composite layer comprises:
a third dielectric layer, disposed on the first composite layer, and configured as a second silicon nitride island structure; and
a fourth dielectric layer, connected to the second silicon nitride island structure, located in gaps of the second silicon nitride island structure, and flush with the second silicon nitride island structure.

14. The gallium nitride transistor as claimed in claim 13, wherein an arrangement density of the first silicon nitride island structure of the first dielectric layer is less than an arrangement density of the second silicon nitride island structure of the third dielectric layer.

15. The gallium nitride transistor as claimed in claim 13, wherein an average width of the gaps defined in the first silicon nitride island structure of the first dielectric layer is greater than an average width of the gaps defined in the second silicon nitride island structure of the third dielectric layer.

16. The gallium nitride transistor as claimed in claim 13, wherein the composite layer further comprises a fifth dielectric layer disposed on the second composite layer, and a surface of the fifth dielectric layer facing away from the semiconductor laminated layer is flat surface.

17. A preparation method of an epitaxial structure of a gallium nitride transistor, comprising:
providing a semiconductor base material;
forming a semiconductor laminated layer on the semiconductor base material, wherein the semiconductor laminated layer comprises a cap layer facing away from the semiconductor base material;
forming a composite layer on the cap layer, wherein the composite layer is a composite structure comprising silicon nitride, and in the composite structure, a proportion of the silicon nitride facing towards the semiconductor laminated layer is less than a proportion of the silicon nitride facing away from the semiconductor laminated layer; and
forming a passivation layer on the composite layer.

18. The preparation method as claimed in claim 17, wherein the composite layer comprises at least two layers, and the forming a composite layer on the cap layer comprises:
forming a first composite layer on the semiconductor laminated layer, wherein the first composite layer comprises:
a first dielectric layer, disposed on the semiconductor laminated layer and configured as a first silicon nitride island structure; and
a second dielectric layer, connected to the first silicon nitride island structure, located in gaps of the first silicon nitride island structure, and flush with the first silicon nitride island structure; and
forming a second composite layer on the first composite layer, wherein the second composite layer comprises:
a third dielectric layer, disposed on the first composite layer, and configured as a second silicon nitride island structure; and
a fourth dielectric layer, connected to the second silicon nitride island structure, located in gaps of the second silicon nitride island structure, and flush with the second silicon nitride island structure.

19. The preparation method as claimed in claim 18, wherein an arrangement density of the first silicon nitride island structure of the first dielectric layer is less than an arrangement density of the second silicon nitride island structure of the third dielectric layer.

20. The preparation method as claimed in claim 18, wherein an average width of the gaps defined in the first silicon nitride island structure of the first dielectric layer is greater than an average width of the gaps defined in the second silicon nitride island structure of the third dielectric layer.
